(19) United States
(12) Patent Application Publication
(10) Pub. No.: US 2026/0143845 A1
(43) Pub. Date: May 21, 2026

(54) SEMICONDUCTOR APPARATUS, IMAGING APPARATUS, RADIATION IMAGING SYSTEM, EQUIPMENT, AND SEMICONDUCTOR APPARATUS MANUFACTURING METHOD

(71) Applicant: CANON KABUSHIKI KAISHA, Tokyo (JP)

(72) Inventors: TSUTOMU TANGE, Kanagawa (JP); TAKASHI USUI, Kanagawa (JP); ALICE MORIMOTO, Kanagawa (JP); YUSUKE TSUKAGOSHI, Kanagawa (JP)

(21) Appl. No.: 19/380,831

(22) Filed: Nov. 5, 2025

(30) Foreign Application Priority Data
Nov. 15, 2024 (JP) 2024-200025

(51) Int. Cl. H10F 39/00; H10F 39/18

(52) U.S. Cl. CPC H10F 39/811; H10F 39/018; H10F 39/18

(57) ABSTRACT

A semiconductor apparatus includes a semiconductor layer, an insulating layer stacked on the semiconductor layer, a through via having conductivity, penetrating the semiconductor layer, extending into the insulating layer, having a recess at an end portion on a side adjacent to the insulating layer, and a connection member having conductivity, disposed in the insulating layer, having a side surface a part of which being in contact with an inner side surface of the recess of the through via. The part of the side surface of the connection member, which is in contact with the through via, extends from a side of the insulating layer to a side of the semiconductor layer with respect to an extension line of an interface between the insulating layer and the semiconductor layer.

### BACKGROUND

### Field of the Technology

The present disclosure relates to a semiconductor apparatus, a semiconductor apparatus manufacturing method, and the like.

### Description of the Related Art

JP 2019-62183 A discloses a technology for improving reliability of an image sensor including an organic photoelectric conversion layer. An image sensor described in JP 2019-62183 A includes a contact via penetrating a substrate and a lower contact plug penetrating a part of an interlayer insulating layer and protruding into the contact via. The lower contact plug protruding into the contact via has a structure in which the lower contact plug is in contact with the contact via only on a substrate side with respect to a boundary surface between the substrate and the interlayer insulating layer.

In a semiconductor apparatus exemplified by an image sensor, it is required to reduce an electrical resistance at a connection portion between conductive members such as a via and a plug. The image sensor described in JP 2019-62183 A has a structure in which the lower contact plug protrudes into the contact via only on the substrate side with respect to the boundary surface between the substrate and the interlayer insulating layer, and there has been a demand for a technology capable of further reducing the electrical resistance at the connection portion.

### SUMMARY

According to a first aspect of the present disclosure, a semiconductor apparatus includes a semiconductor layer, an insulating layer stacked on the semiconductor layer, a through via having conductivity, penetrating the semiconductor layer, extending into the insulating layer, having a recess at an end portion on a side adjacent to the insulating layer, and a connection member having conductivity, disposed in the insulating layer, having a side surface a part of which being in contact with an inner side surface of the recess of the through via. The part of the side surface of the connection member, which is in contact with the through via, extends from a side of the insulating layer to a side of the semiconductor layer with respect to an extension line of an interface between the insulating layer and the semiconductor layer.

According to a second aspect of the present disclosure, a semiconductor apparatus manufacturing method includes preparing a second substrate including a semiconductor layer in which semiconductor elements are formed, an element isolation region that isolates the semiconductor elements, and an insulating layer provided so as to cover the semiconductor layer and the element isolation region, forming, in the second substrate, a first opening that penetrates the insulating layer and reaches a part of the element isolation region, forming a connection member having conductivity by filling the first opening with a conductive material, forming, in the second substrate, a second opening that penetrates the semiconductor layer and the element isolation region, reaches a part of the insulating layer, and exposes a part of the connection member, and forming a through via having conductivity by filling the second opening with the conductive material. An electrical connection structure in which the through via and the connection member are bonded to each other is formed, the through via penetrating the semiconductor layer, extending into the insulating layer, and having a recess at an end portion on a side adjacent to the insulating layer, the connection member being disposed in the insulating layer and having a part of a side surface in contact with an inner side surface of the recess of the through via.

Features of the present disclosure will become apparent from the following description of embodiments with reference to the attached drawings. The following description of embodiments is described by way of example.

### BRIEF DESCRIPTION OF THE DRAWINGS

FIG. 1 is a schematic cross-sectional view for showing a stacked structure of a photoelectric conversion apparatus according to a first embodiment.

FIG. 2 is a schematic enlarged cross-sectional view showing the vicinity of a connection portion between a through via and a connection member.

FIG. 3 is a schematic enlarged cross-sectional view showing the vicinity of a connection portion between a through via and a connection member in a first modified example.

FIG. 4 is a schematic enlarged cross-sectional view showing the vicinity of a connection portion between a through via and a connection member in a second modified example.

FIG. 5 is a schematic enlarged cross-sectional view showing the vicinity of a connection portion between a through via and a connection member in a third modified example.

FIG. 6 is a schematic cross-sectional view for describing one stage of a procedure for manufacturing a first circuit substrate.

FIG. 7 is a schematic cross-sectional view for describing a procedure for forming the connection member.

FIG. 8 is a schematic cross-sectional view for describing a procedure for forming a wiring structure including a bonding electrode E12.

FIG. 9 is a schematic cross-sectional view for describing a procedure for bonding the first circuit substrate and a sensor substrate.

FIG. 10 is a schematic cross-sectional view for describing a procedure for thinning a second semiconductor substrate SL2SUB as necessary to form a second semiconductor layer SL2.

FIG. 11 is a schematic cross-sectional view for describing a procedure for forming an opening TH for forming a through via.

FIG. 12 is a schematic cross-sectional view for describing a procedure for forming an insulating film so as to cover a side wall of the opening TH.

FIG. 13 is a schematic cross-sectional view for describing a procedure for filling the opening TH with a conductive material to form the through via.

FIG. 14 is a schematic cross-sectional view for describing a procedure for forming a bonding electrode E21 on the through via.

FIG. 15 is a schematic cross-sectional view for describing a procedure for integrating three substrates, the sensor substrate 11, the first circuit substrate 21, and the second circuit substrate 31.

FIG. 16A is a schematic diagram for describing equipment according to a second embodiment.

FIG. 16B is a schematic diagram showing an example of a photoelectric conversion system according to the second embodiment.

FIG. 16C is a schematic diagram showing an example of an in-vehicle photoelectric conversion system according to the second embodiment.

FIG. 17A is a schematic diagram showing equipment serving as a radiation imaging system according to a third embodiment.

FIG. 17B is a schematic diagram showing a configuration of a transmission electron microscope serving as the radiation imaging system according to the third embodiment.

### DESCRIPTION OF THE EMBODIMENTS

A semiconductor apparatus, a semiconductor apparatus manufacturing method, and the like according to embodiments of the present disclosure will be described with reference to the drawings. The embodiments described below are merely examples, and for example, detailed configurations can be appropriately changed and implemented by those skilled in the art without departing from the gist of the present disclosure.

In the drawings referred to in the following embodiments and description, elements denoted by the same reference signs have similar functions unless otherwise specified. In the drawings, in a case where a plurality of the same elements are arranged, reference signs and a description thereof may be omitted.

In addition, the drawings may be schematic for convenience of illustration and description, and thus, the shape, size, arrangement, and the like of elements in the drawings may not strictly match those of actual ones. In addition, “XX or more and YY or less” or “XX to YY” representing a numerical range means a numerical range including end points XX (lower limit) and YY (upper limit) unless otherwise specified. When numerical ranges are described in stages, the upper limit and the lower limit of each numerical range can be arbitrarily combined.

In the following description, for example, a +X direction indicates the same direction as that indicated by an X-axis arrow in the shown orthogonal coordinate system, and a −X direction indicates a direction 180 degrees opposite to that indicated by the X-axis arrow in the shown orthogonal coordinate system. In addition, a direction simply referred to as the X direction is a direction parallel to the X axis regardless of a difference from the direction indicated by the shown X-axis arrow. The same applies to directions other than the X direction. In the following description, terms (such as “upper”, “lower”, “right”, “left”, and other terms including these terms) indicating specific directions or positions are used as necessary. The use of these terms is to facilitate understanding of the embodiments with reference to the drawings, and the technical scope of the present disclosure is not limited by the meaning of these terms.

In the following description, terms “layer” and “film” may be used like an insulating layer and an insulating film, but the terms do not mean technically different aspects unless otherwise specified.

A relationship of “being substantially equal” used in the following description will be described. Even in the case of a relationship of being equal in design, a slight difference may occur due to a manufacturing error. The term “substantially equal” includes a slight difference caused by such a manufacturing error.

### First Embodiment

### Configuration of Photoelectric Conversion Apparatus

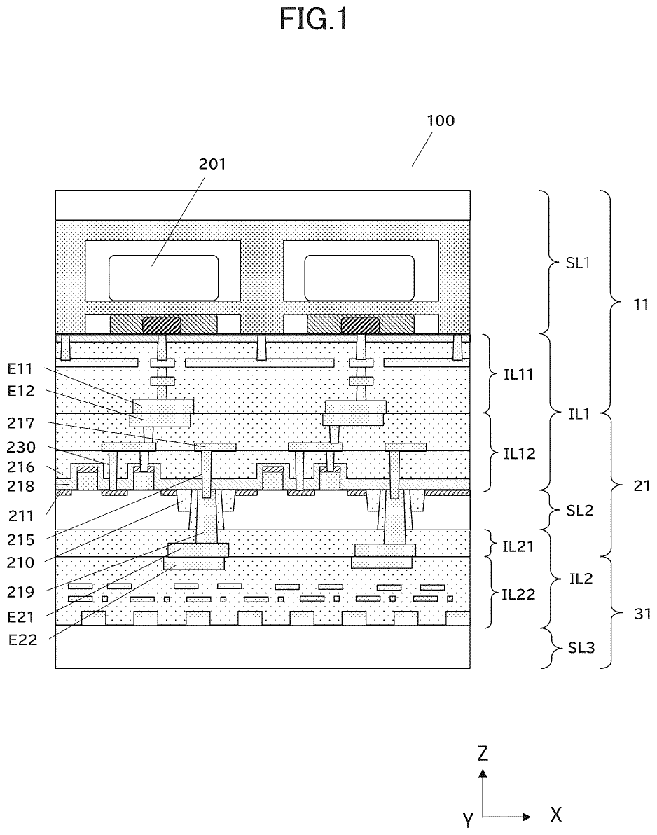

A configuration of a photoelectric conversion apparatus according to a first embodiment will be described with reference to the drawings. FIG. 1 is a schematic cross-sectional view for showing a stacked structure of the photoelectric conversion apparatus according to the first embodiment. A photoelectric conversion apparatus 100 as an example is implemented as a stacked-type photoelectric conversion apparatus. The photoelectric conversion apparatus 100 may be, for example, a back-side illuminated photoelectric conversion apparatus, but the photoelectric conversion apparatus according to the present disclosure may be implemented as a front-illuminated photoelectric conversion apparatus.

The photoelectric conversion apparatus 100 is implemented by, for example, stacking a plurality of substrates including a sensor substrate 11, a first circuit substrate 21, and a second circuit substrate 31, and electrically connecting the plurality of substrates.

Each of the sensor substrate 11, the first circuit substrate 21, and the second circuit substrate 31 may be a chip diced from a wafer, but the substrates are not limited to the chip. For example, each substrate may be a wafer. The plurality of substrates may be stacked in a wafer state and then diced, or the plurality of substrates may be diced into a plurality of chips, and then the plurality of chips may be stacked or bonded.

The sensor substrate 11 has a pixel array region in which a plurality of photoelectric conversion elements 201 are disposed. The sensor substrate 11 includes a first semiconductor layer SL1 including the photoelectric conversion elements 201 and an insulating layer IL11 having a multilayer wiring structure. The insulating layer IL11 can be formed as an interlayer insulating layer having the multilayer wiring structure electrically connected to the photoelectric conversion elements 201.

The first circuit substrate 21 includes a second semiconductor layer SL2 in which a plurality of semiconductor elements (for example, transistors) included in a circuit such as a first signal processing unit and an element isolation region 210 that isolates the semiconductor elements are disposed. Furthermore, the first circuit substrate 21 includes an insulating layer IL12 having a multilayer wiring structure and an insulating layer IL21 including a wiring structure.

The insulating layer IL12 can be formed as an interlayer insulating layer having the multilayer wiring structure that electrically connects the sensor substrate 11 and the first signal processing unit. The insulating layer IL12 includes an insulating film 216 and an insulating layer 218. The insulating layer IL21 can be formed as an interlayer insulating layer having the wiring structure that electrically connects the first signal processing unit and the second circuit substrate 31. The insulating layer IL12 and the insulating layer IL21 are stacked on opposite sides of the second semiconductor layer SL2, respectively. The second semiconductor layer SL2 includes a silicide layer 211 at an interface with the insulating layer IL12 (insulating layer 218).

The first circuit substrate 21 includes a through via 219 provided so as to penetrate the second semiconductor layer SL2 in order to electrically connect a wiring pattern 217 formed in the insulating layer IL12 and a wiring included in the second circuit substrate 31. The through via 219 made of a conductive material penetrates at least a part of the insulating layer IL21 and the second semiconductor layer SL2 and extends to at least a part (inside) of the insulating layer IL12. The wiring pattern 217 and the through via 219 are connected by a connection member 215 made of a conductive material. The connection member 215 penetrates at least a part of the insulating layer IL12 and extends into a recess of the through via 219. A connection portion between the through via 219 and the connection member 215 and a peripheral structure thereof are described in detail below.

The second circuit substrate 31 has a second circuit region in which circuits such as a second signal processing unit, a vertical scanning circuit, a horizontal scanning circuit, and a reading circuit are disposed. In addition, the second circuit substrate 31 includes a third semiconductor layer SL3 in which a plurality of semiconductor elements (for example, transistors) included in a circuit such as the second signal processing unit are disposed, and an insulating layer IL22 having a multilayer wiring structure. The insulating layer IL22 can be formed as an interlayer insulating layer having the multilayer wiring structure electrically connected to the first circuit substrate 21.

A first insulating layer IL1 in which the insulating layer IL11 and the insulating layer IL12 are connected is interposed between the first semiconductor layer SL1 of the sensor substrate 11 and the second semiconductor layer SL2 of the first circuit substrate 21. A second insulating layer IL2 in which the insulating layer IL21 and the insulating layer IL22 are connected is interposed between the second semiconductor layer SL2 of the first circuit substrate 21 and the third semiconductor layer SL3 of the second circuit substrate 31.

The sensor substrate 11 and the first circuit substrate 21 are bonded such that the first insulating layer IL11 and the insulating layer IL12 are adjacent to each other. At a bonding portion between the sensor substrate 11 and the first circuit substrate 21, a bonding electrode E11 disposed in the insulating layer IL11 and a bonding electrode E12 disposed in the insulating layer IL12 form a metal bond, and electrically and mechanically connect the sensor substrate 11 and the first circuit substrate 21 to each other. That is, a wiring structure (electrical connection structure) electrically connecting the photoelectric conversion elements 201 formed in the first semiconductor layer SL1 and a first circuit region formed in the first circuit substrate 21 is formed in the first insulating layer IL1.

The first circuit substrate 21 includes the insulating layer IL21 formed on a side of the semiconductor layer SL2 that is opposite to the insulating layer IL12. At a bonding portion between the first circuit substrate 21 and the second circuit substrate 31, a bonding electrode E21 disposed in the insulating layer IL21 and a bonding electrode E22 disposed in the insulating layer IL22 form a metal bond, and electrically and mechanically connect the first circuit substrate 21 and the second circuit substrate 31 to each other. That is, a wiring structure (electrical connection structure) electrically connecting the first circuit region formed in the first circuit substrate 21 and the second circuit region formed in the second circuit substrate 31 is formed in the second insulating layer IL2.

### Through Via and Connection Member

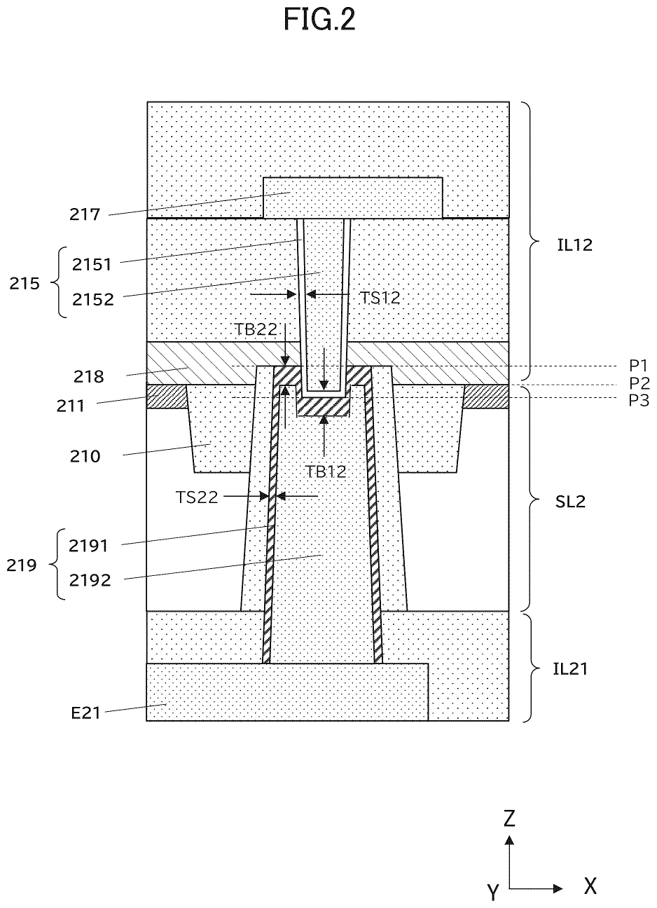

Next, a characteristic portion of the present embodiment, that is, a structure for reducing a connection electrical resistance between the through via 219 and the connection member 215 will be described. FIG. 2 is a schematic enlarged cross-sectional view showing the connection portion between the through via 219 and the connection member 215 and the vicinity thereof. In FIG. 2, a main surface of the first circuit substrate 21 or the second semiconductor layer SL2 is parallel to an XY plane, and a normal direction with respect to the main surface of the first circuit substrate 21 or the second semiconductor layer SL2 is the Z direction. A layer structure schematically shown in FIG. 2 can be confirmed by observing a cross-sectional sample of the photoelectric conversion apparatus 100 or the first circuit substrate 21 using an appropriate analyzer such as a transmission electron microscope (TEM) or a scanning electron microscope (SEM) or an appropriate analysis method.

In the first circuit substrate 21, the through via 219 and the connection member 215 electrically connect the wiring pattern 217 disposed in the insulating layer IL12 and the bonding electrode E21 disposed in the insulating layer IL21. The wiring pattern 217 may be formed of, for example, copper or aluminum, and may also be formed of another material.

The through via 219 may be formed of, for example, tungsten, and may also be formed of another conductive material such as aluminum or copper. The through via 219 can be formed in a two-layer structure including a conductive core material 2192 and a conductive covering material 2191 covering the core material 2192. The core material 2192 which is a central portion or a base portion of the through via 219 can be formed of, for example, a metal material such as tungsten, aluminum, or copper, or another alloy material, and the covering material 2191 can be formed as a barrier metal using, for example, Ti or TiN.

The silicide layer 211 is formed on a +Z direction side (insulating layer IL12 side) surface of the second semiconductor layer SL2. The element isolation region 210 for isolating the semiconductor elements can be disposed at a portion of the second semiconductor layer SL2 where the silicide layer 211 is not disposed. Although the through via 219 needs to be disposed while avoiding the silicide layer 211, it is advantageous to dispose the through via 219 so as to penetrate the element isolation region 210 as shown in FIG. 2 in terms of simplifying a circuit layout and a process.

The connection member 215 that connects the wiring pattern 217 and the through via 219 to each other can be formed in a two-layer structure including a conductive core material 2152 and a conductive covering material 2151 that covers the core material 2152. The core material 2152 which is a central portion or a base portion of the connection member 215 can be formed of, for example, a metal material such as tungsten, aluminum, or copper, or another alloy material, and the covering material 2151 can be formed as a barrier metal using, for example, Ti or TiN. The connection member 215 can be, for example, a plug.

For convenience of explanation, a dimension of the through via 219 in the Z direction is referred to as a height of the through via 219, and a diameter of the through via 219 in a cross section parallel to the XY plane is referred to as a width of the through via 219. A dimension of the connection member 215 in the Z direction is referred to as a height of the connection member 215, and a diameter of the connection member 215 in a cross section parallel to the XY plane is referred to as a width of the connection member 215.

According to a configuration in which the through via 219 is electrically connected to the wiring pattern 217 via the connection member 215, the height of the through via 219 can be reduced, in other words, a depth of a through hole formed for forming the through via 219 can be reduced. This is advantageous for stably forming the fine through via 219. In addition, such a structure is also advantageous in that the wiring pattern 217 is not damaged by etching when the through hole for forming the through via 219 is formed by etching. In order to reduce the height of the through via 219, the second semiconductor layer SL2 may be smaller in thickness than the other semiconductor layers. For example, the second semiconductor layer SL2 may be smaller in thickness than any of the first semiconductor layer SL1 and the third semiconductor layer SL3.

The through via 219 may have a tapered shape in which the width decreases toward a connection member side. In addition, the connection member 215 may have a tapered shape in which the width decreases toward a through via side. At the connection portion between the through via 219 and the connection member 215, the width of the through via 219 is larger than the width of the connection member 215. By adopting such a configuration, a requirement for accuracy in alignment of the through via 219 with respect to the connection member 215 can be alleviated at the time of manufacturing.

The recess that is recessed in the −Z direction is formed at an upper end portion (an end portion in the +Z direction) of the through via 219, and a lower end portion (an end portion in the −Z direction) of the connection member 215 extends into the recess, whereby the through via 219 and the connection member 215 are firmly connected to each other. That is, a side surface of the recess of the through via 219 and a side surface of the lower end portion of the connection member 215 are bonded to each other, and a bottom surface of the recess of the through via 219 and a distal end surface of the lower end portion of the connection member 215 are bonded to each other.

As shown in the figure, in the normal direction (Z direction) with respect to the main surface of the first circuit substrate 21 or the second semiconductor layer SL2, a position of an upper end of the through via 219 is P1, a position of a boundary surface between the insulating layer IL12 and the second semiconductor layer SL2 is P2, and a position of a lower end of the connection member 215 is P3.

As is clear from a shown positional relationship between P1 and P2, the upper end of the through via 219 is positioned closer to the insulating layer IL12 than an extension line of the boundary surface between the insulating layer IL12 and the second semiconductor layer SL2. That is, the through via 219 penetrates the second semiconductor layer SL2 and at least partially extends into the insulating layer IL12.

As can be seen from a positional relationship between P2 and P3, the lower end of the connection member 215 is positioned on a side of the second semiconductor layer SL2 with respect to the extension line of the boundary surface between the insulating layer IL12 and the second semiconductor layer SL2. That is, the connection member 215 penetrates a part of the insulating layer IL12 and at least partially extends into the second semiconductor layer SL2.

According to the present embodiment, the side surface of the recess of the through via 219 and the side surface of the lower end portion of the connection member 215 are bonded to each other over a wide area from P1 in the insulating layer IL12 to P3 in the second semiconductor layer SL2. That is, side surfaces of the through via 219 and the connection member 215 are bonded to each other over a wide area so as to sandwich the position (P2) of the boundary surface between the insulating layer IL12 and the second semiconductor layer SL2. In other words, a part of the side surface of the connection member 215 that is in contact with the through via 219 extends from the insulating layer IL12 to the semiconductor layer SL2 with respect to an extension line of P2, which is an interface between the insulating layer IL12 and the semiconductor layer SL2.

As described above, not only a distal end surface of the through via 219 and a distal end surface of the connection member 215 but also an inner side surface of the recess of the through via 219 and the side surface of the lower end portion of the connection member 215 are bonded to each other over a wide area. Therefore, according to the present embodiment, a conduction failure and a resistance variation at the connection portion between the connection member 215 and the through via 219 can be significantly reduced.

The covering material 2151 included in the connection member 215 can be formed by, for example, chemical vapor deposition (CVD) which is a film forming technology (film forming method) having a small anisotropy in deposition rate. In addition, the covering material 2191 included in the through via 219 can be formed by, for example, sputtering which is a film forming technology having a high anisotropy in deposition rate (material directivity). According to such a manufacturing method, a film thickness of each portion can satisfy relationships of TB12>TB22>TS22 and TB12>TS12. TS12 is a thickness of the covering material 2151 on the side surface of the connection member 215, and TB22 is a thickness of the covering material 2191 on an upper surface of the through via 219, that is, a portion that is in contact with the insulating layer 218. TS22 is a thickness of the covering material 2191 on the side surface of the through via 219. TB12 is the total film thickness of the covering material 2151 and the covering material 2191 on the bottom surface of the recess of the through via 219. As an example, the film thickness TS12 can be 5 nm to 30 nm, the film thickness TS22 can be 5 nm to 60 nm, the film thickness TB22 can be 5 nm to 90 nm, and the film thickness TB12 can be 10 nm to 120 nm.

As described above, the connection member 215 includes the conductive core material 2152 and the conductive covering material 2151 covering the core material 2152. The thickness TS12 of the covering material 2151 covering a side surface of the core material 2152 is substantially equal to a thickness (TB12-TB22) of the covering material covering an end surface of the core material 2152 on a side adjacent to the through via 219. The through via 219 includes the conductive core material 2192 and the conductive covering material 2191 covering the core material 2192. The thickness TS22 of the covering material 2191 covering a side surface of the core material 2192 is smaller than the thickness TB22 of the covering material 2191 covering a distal end surface of the core material 2192, which is adjacent to the insulating layer 218, or the bottom surface of the recess.

The manufacturing methods and configurations of the covering material 2151 of the connection member 215 and the covering material 2191 of the through via 219 may be different. Hereinafter, modified examples will be described.

### First Modified Example

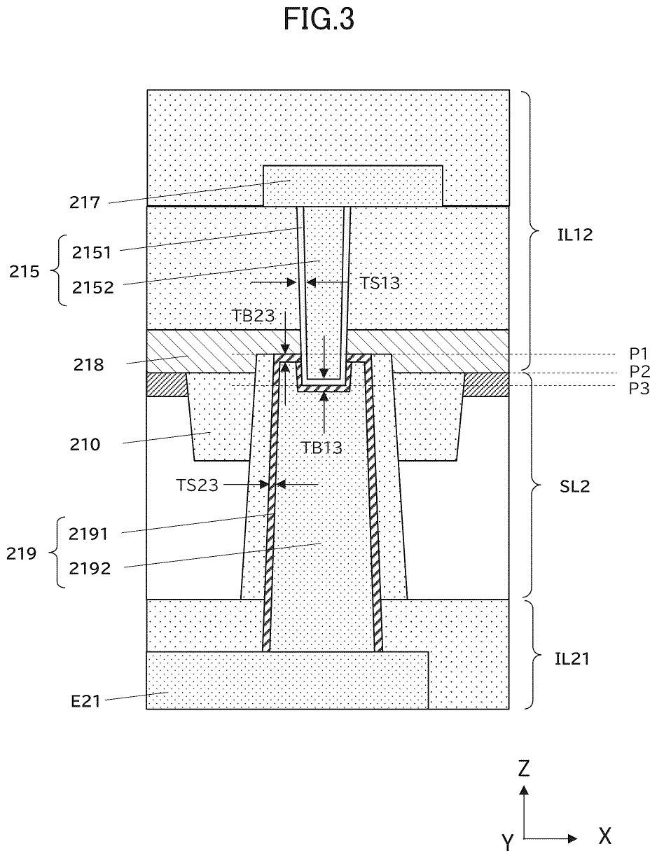

FIG. 3 is a schematic enlarged cross-sectional view showing a connection portion between a through via 219 and a connection member 215 and the vicinity thereof in a first modified example. A description of matters common to the embodiment shown in FIG. 2 will be omitted.

A covering material 2151 included in the connection member 215 is formed by, for example, CVD which is a film forming technology having a small anisotropy in deposition rate. A covering material 2191 of the through via 219 is formed by, for example, CVD which is a film forming technology having a small anisotropy in deposition rate. According to such a manufacturing method, a film thickness of each portion can satisfy relationships of TB13>TB23≈TS23, and TB13>TS13. TS13 is a thickness of the covering material 2151 on a side surface of the connection member 215, and TB23 is a thickness of the covering material 2191 on an upper surface of the through via 219, that is, a portion that is in contact with an insulating layer 218. TS23 is a thickness of the covering material 2191 on a side surface of the through via 219. TB13 is the total film thickness of the covering material 2151 and the covering material 2191 on a bottom surface of a recess of the through via 219. As an example, the film thickness TS13 can be 5 nm to 30 nm, the film thickness TS23 can be 5 nm to 30 nm, the film thickness TB23 can be 5 nm to 30 nm, and the film thickness TB13 can be 10 nm to 60 nm.

### Second Modified Example

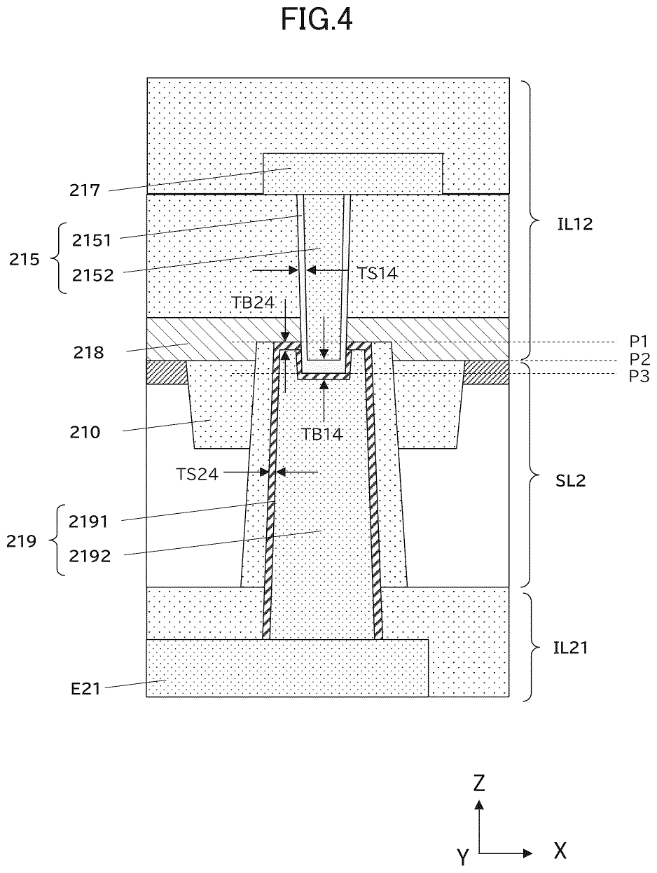

FIG. 4 is a schematic enlarged cross-sectional view showing a connection portion between a through via 219 and a connection member 215 and the vicinity thereof in a second modified example. A description of matters common to the aspect shown in FIG. 2 will be omitted.

A covering material 2151 of the connection member 215 is formed such that a deposition rate (material directivity) in the Z direction increases by using, for example, sputtering which is a film forming technology having anisotropy in deposition rate. A covering material 2191 of the through via 219 is formed by, for example, CVD which is a film forming technology having a small anisotropy in deposition rate. According to such a manufacturing method, a film thickness of each portion can satisfy relationships of TB14>TB24≈TS24, and TB14>TS14. TS14 is a thickness of the covering material 2151 on a side surface of the connection member 215, and TB24 is a thickness of the covering material 2191 on an upper surface of the through via 219, that is, a portion that is in contact with an insulating layer 218. TS24 is a thickness of the covering material 2191 on a side surface of the through via 219. TB14 is the total film thickness of the covering material 2151 and the covering material 2191 on a bottom surface of a recess of the through via 219. As an example, the film thickness TS14 can be 5 nm to 60 nm, the film thickness TS24 can be 5 nm to 30 nm, the film thickness TB24 can be 5 nm to 30 nm, and the film thickness TB14 can be 10 nm to 120 nm.

### Third Modified Example

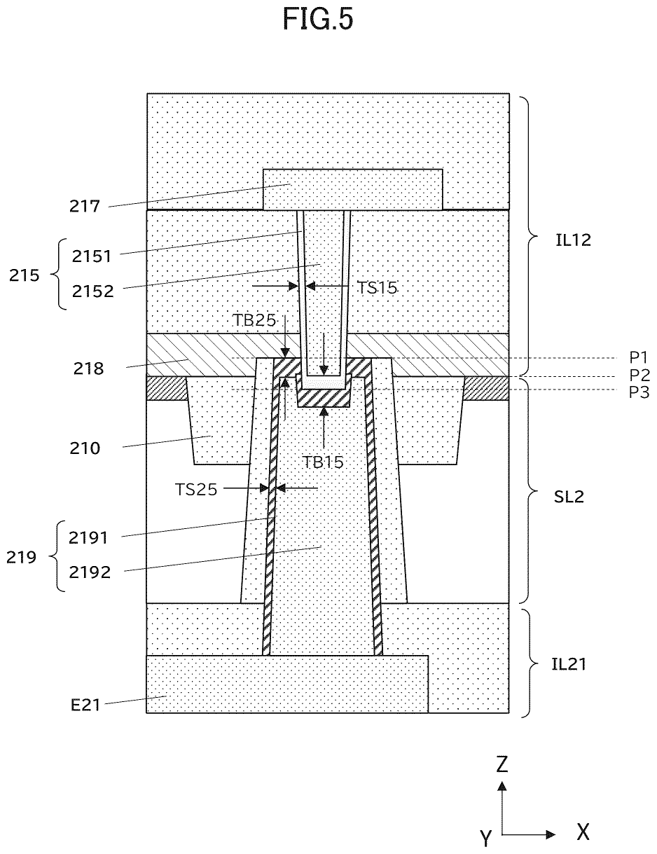

FIG. 5 is a schematic enlarged cross-sectional view showing a connection portion between a through via 219 and a connection member 215 and the vicinity thereof in a third modified example. A description of matters common to the aspect shown in FIG. 2 will be omitted.

A covering material 2151 of the connection member 215 is formed such that a deposition rate in the Z direction increases by using, for example, sputtering which is a film forming technology having anisotropy in deposition rate. A covering material 2191 of the through via 219 is formed such that a deposition rate in the Z direction increases by using, for example, sputtering which is a film forming technology having anisotropy in deposition rate. According to such a manufacturing method, a film thickness of each portion can satisfy relationships of TB15>TB25>TS25, and TB15>TS15. TS15 is a thickness of the covering material 2151 on a side surface of the connection member 215, and TB25 is a thickness of the covering material 2191 on an upper surface of the through via 219, that is, a portion that is in contact with an insulating layer 218. TS25 is a thickness of the covering material 2191 on a side surface of the through via 219. TB15 is the total film thickness of the covering material 2151 and the covering material 2191 on a bottom surface of a recess of the through via 219. As an example, the film thickness TS15 can be 5 nm to 60 nm, the film thickness TS25 can be 5 nm to 60 nm, the film thickness TB25 can be 5 nm to 90 nm, and the film thickness TB15 can be 10 nm to 180 nm.

### Manufacturing Method

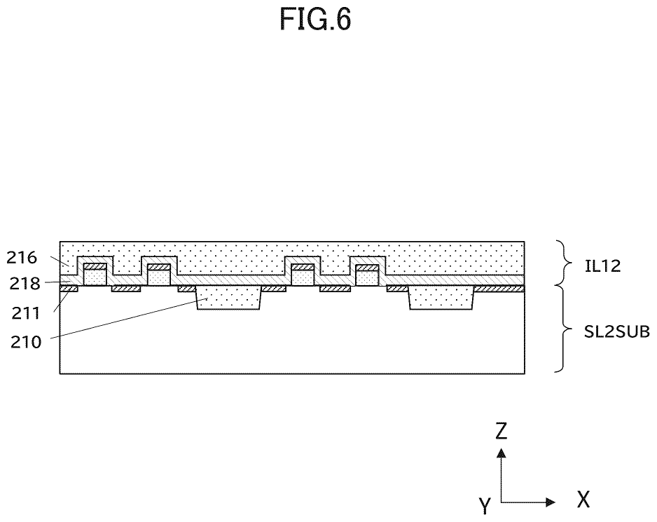

A method for manufacturing the photoelectric conversion apparatus according to the present embodiment will be described with reference to FIGS. 6 to 15. FIGS. 6 to 15 are schematic cross-sectional views for describing each stage of a manufacturing process of the photoelectric conversion apparatus. First, a manufacturing procedure of the first circuit substrate 21 (FIG. 1) will be described.

As shown in FIG. 6, the element isolation region 210 in which, for example, an oxide film is embedded in a groove, and a transistor including the silicide layer 211 are formed in a second semiconductor substrate SL2SUB for forming the second semiconductor layer SL2. Further, the insulating layer 218 and the insulating film 216 are sequentially formed on the second semiconductor substrate SL2SUB. The insulating layer 218 can be, for example, a silicon nitride film. The insulating film 216 can be, for example, a silicon oxide film. A thickness of the insulating layer 218 can be 10 nm to 100 nm. An insulating film (not shown) may be further formed between the insulating layer 218 and the second semiconductor substrate SL2SUB.

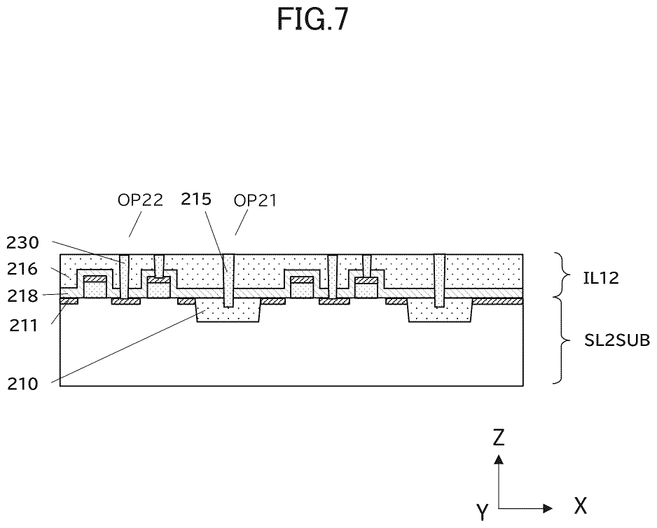

Next, as shown in FIG. 7, the insulating film 216 is etched to form a first opening OP21 and a second opening OP22. The first opening OP21 penetrates the insulating layer 218 and reaches a predetermined depth (P3 in FIG. 2) in the element isolation region 210, but etching conditions for the second opening OP22 are adjusted such that etching is stopped at a position where the silicide layer 211 is exposed.

Subsequently, the first opening OP21 is filled with a conductive material to form the connection member 215, and the second opening OP22 is filled with a conductive material to form a contact plug 230 (FIG. 1). Here, the connection member 215 is formed so as to penetrate the insulating layer 218 and reach a predetermined depth (P3 in FIG. 2) in the element isolation region 210.

The connection member 215 and the contact plug 230 can be formed of, for example, a barrier metal such as Ti or TiN and tungsten, and may also be formed of another material such as aluminum or copper or a combination thereof. The connection member 215 connected to the through via 219 can be formed simultaneously with the contact plug 230 connected to the transistor or the like. Further, after the first opening OP21 is formed, the second opening OP22 connected to the transistor or the like can be formed to form the connection member 215 and the contact plug 230.

At this time, a diameter of the first opening OP21 is desirably equal to or larger than a diameter of the second opening OP22. Due to the circuit layout, the diameter of the second opening OP22 for forming the contact plug 230 connected to the transistor or the like is desirably small. On the other hand, the diameter of the first opening OP21 for forming the connection member 215 is desirably equal to or larger than the diameter of the second opening OP22 from the viewpoint of facilitating alignment with the through via 219 to be connected later and reducing the connection electrical resistance.

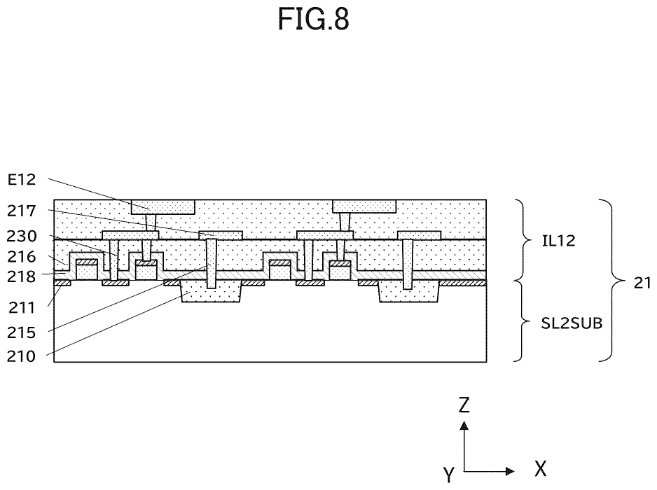

Next, as shown in FIG. 8, a wiring structure further including a wiring layer is formed on the connection member 215 and the contact plug 230. In the uppermost layer of the wiring structure, the bonding electrode E12 is formed so as to be exposed on an upper surface of the insulating layer IL12. In this way, a part of the first circuit substrate 21 is formed.

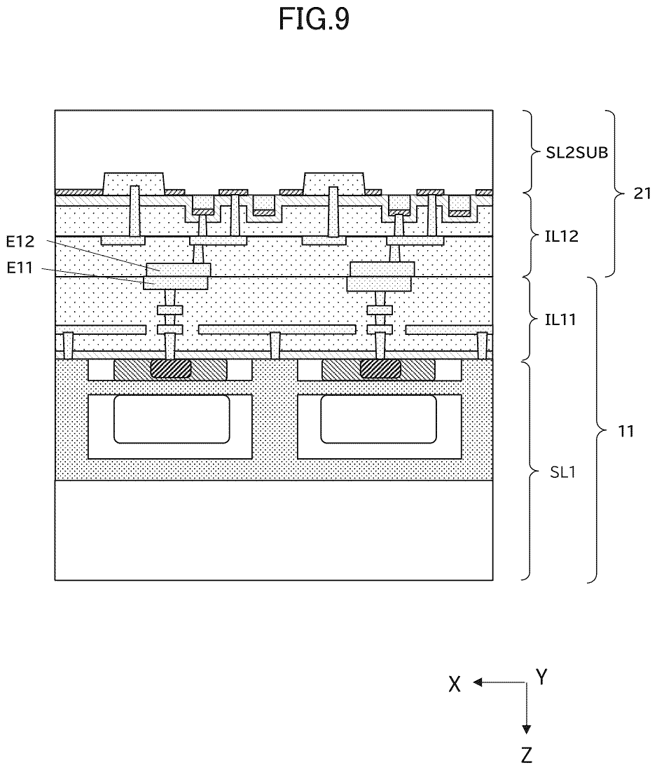

Next, as shown in FIG. 9, a part of the first circuit substrate 21 described above and the separately prepared sensor substrate 11 are bonded to each other. FIG. 9 is shown in a vertically inverted manner with respect to FIG. 8. At this time, the bonding electrode E11 formed in the sensor substrate 11 and the bonding electrode E12 formed in the first circuit substrate 21 are bonded to each other, and the sensor substrate 11 and the first circuit substrate 21 are electrically and mechanically connected to each other.

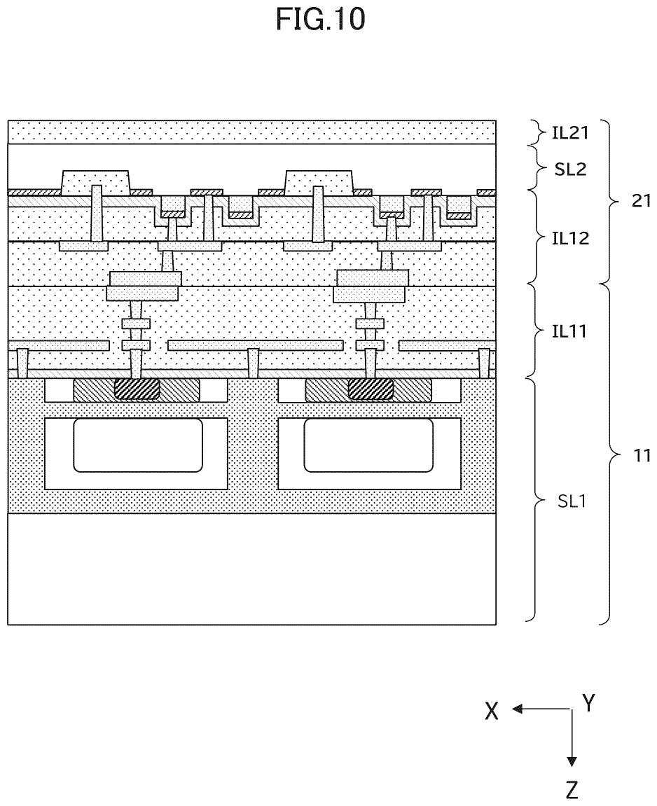

Next, as shown in FIG. 10, the second semiconductor substrate SL2SUB is thinned as necessary to form the second semiconductor layer SL2. Further, the insulating layer IL21 is formed on the second semiconductor layer SL2.

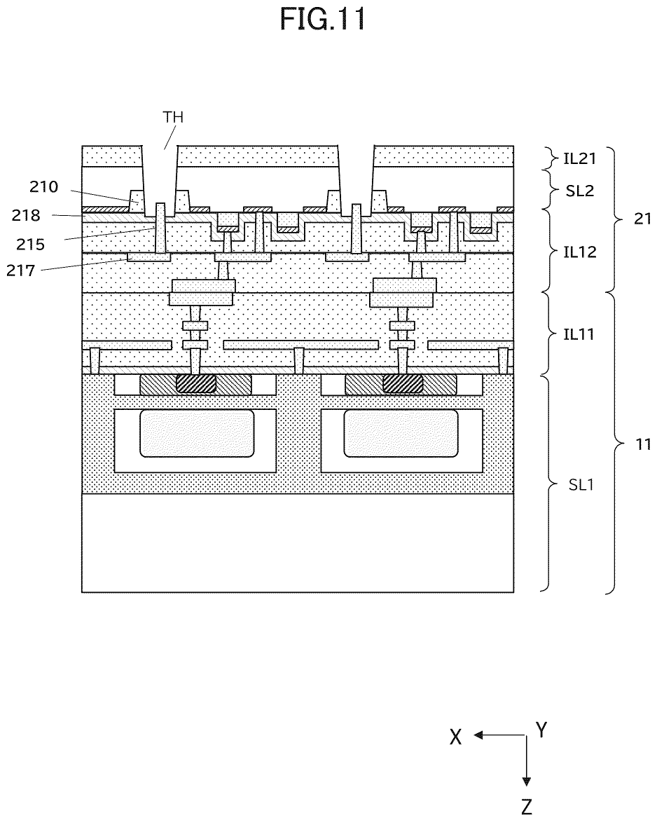

Next, as shown in FIG. 11, an opening TH is formed. The opening TH is formed by penetrating the insulating layer IL21, the second semiconductor layer SL2, and the element isolation region 210 and further digging a part of the insulating layer 218 to P1 in FIG. 2 by etching. A part of the connection member 215 protrudes from the insulating layer 218 at a bottom portion of the opening TH.

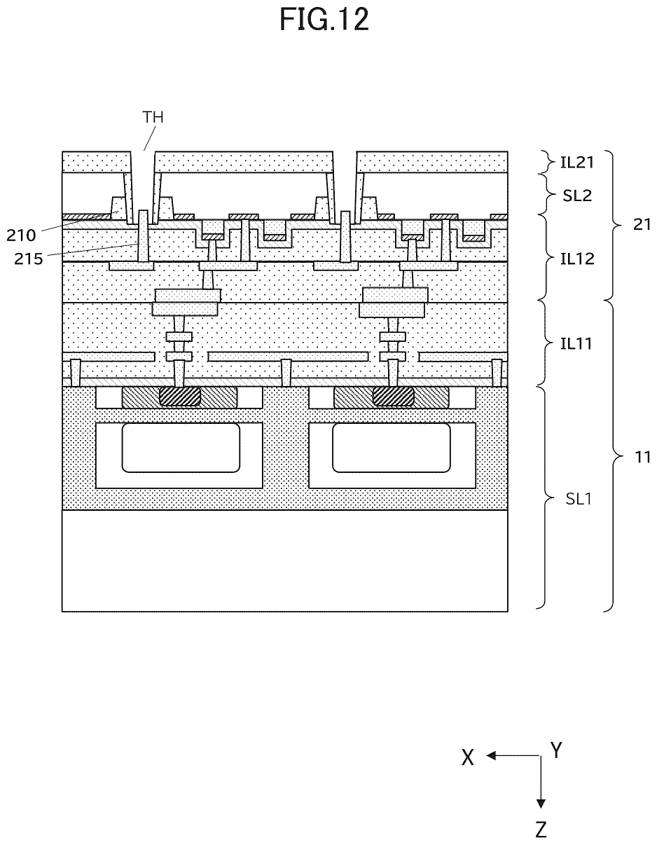

Next, as shown in FIG. 12, an insulating film is formed so as to cover a side wall of the opening TH. For example, the insulating film can be formed so as to cover an inner surface of the opening, and then, a portion of the insulating film that is positioned at the bottom portion of the opening TH can be removed by using an etch-back process or the like.

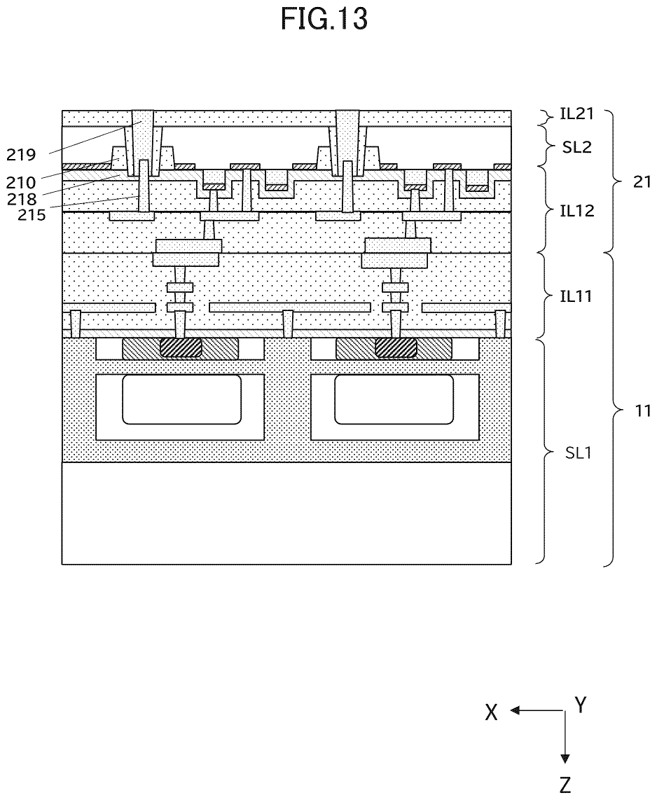

Next, as shown in FIG. 13, the through via 219 described with reference to FIG. 2 is formed, for example, by filling the opening TH with a conductive material. That is, the through via 219 penetrating the second semiconductor layer SL2 and connected to the connection member 215 is formed. As shown in FIG. 2, a distal end of the through via 219 is positioned at P1 in the insulating layer 218. The through via 219 can be formed of, for example, a barrier metal such as Ti or TiN and tungsten, and may also be formed of another material such as aluminum or copper.

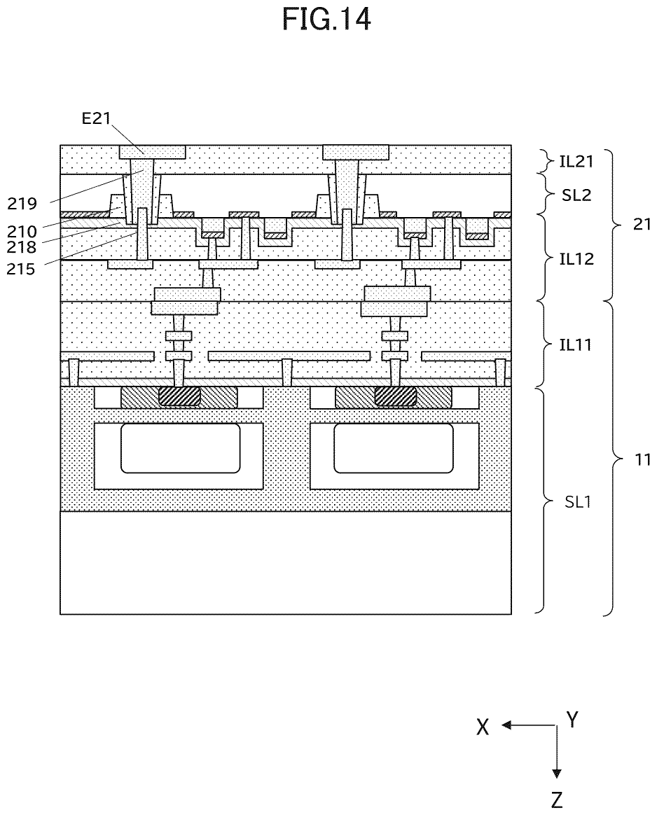

Next, as shown in FIG. 14, the bonding electrode E21 is formed on the through via 219. Although not shown here, it is also possible to form a wiring structure including a wiring layer between the through via 219 and the bonding electrode E21.

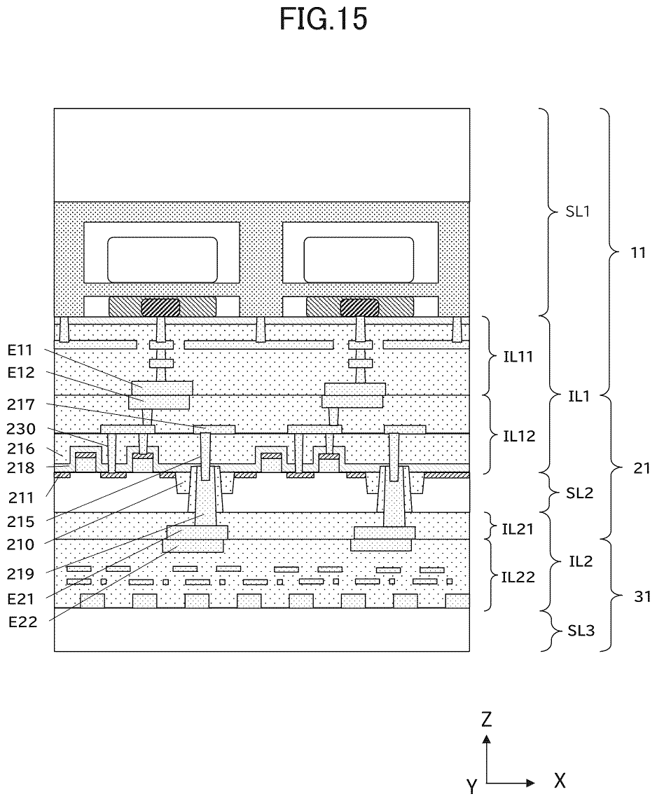

Next, as shown in FIG. 15, the separately prepared second circuit substrate 31 is bonded to a bonded body of the first circuit substrate 21 and the sensor substrate 11, which is formed in FIG. 14. FIG. 15 is shown in a vertically inverted manner with respect to FIG. 14. At this time, the bonding electrode E21 of the first circuit substrate 21 and the bonding electrode E22 of the second circuit substrate 31 are bonded to each other, and the first circuit substrate 21 and the second circuit substrate 31 are electrically and mechanically connected to each other. As a result, three substrates including the sensor substrate 11, the first circuit substrate 21, and the second circuit substrate 31 are integrated and electrically and mechanically connected to one another. Thereafter, the first semiconductor layer SL1 is thinned as necessary, and the photoelectric conversion apparatus 100 shown in FIG. 1 is completed.

According to the manufacturing method described above, as shown in FIG. 7, the connection member 215 is formed so as to penetrate the insulating layer 218 and reach a predetermined depth (P3 in FIG. 2) in the element isolation region 210. Then, as shown in FIG. 13, the through via 219 is formed, the through via 219 penetrating the second semiconductor layer SL2, having the distal end positioned in the insulating layer 218, and being connected to the connection member 215.

As a result, one end of the through via 219 is positioned on a side of the insulating layer IL12 with respect to the extension line of the boundary surface between the insulating layer IL12 and the second semiconductor layer SL2. That is, the through via 219 penetrates the second semiconductor layer SL2 and at least partially extends into the insulating layer IL12.

One end of the connection member 215 is positioned on a side of the second semiconductor layer SL2 with respect to the extension line of the boundary surface between the insulating layer IL12 and the second semiconductor layer SL2. That is, the connection member 215 penetrates a part of the insulating layer IL12 and at least partially extends into the second semiconductor layer SL2.

According to the present embodiment, the inner side surface of the recess of the through via 219 and the side surface of the end portion of the connection member 215 are bonded to each other over a wide area from P1 in the insulating layer IL12 to P3 in the second semiconductor layer SL2. In other words, the side surfaces of the through via 219 and the connection member 215 are bonded to each other over a wide area so as to sandwich the position (P2) of the boundary surface between the insulating layer IL12 and the second semiconductor layer SL2. As described above, not only the bottom surface of the recess of the through via 219 and the distal end surface of the end portion of the connection member 215 but also the inner side surface of the recess of the through via 219 and the side surface of the end portion of the connection member 215 are bonded to each other over a wide area. Therefore, in the present embodiment, the connection electrical resistance at the connection portion between the connection member 215 and the through via 219 can be reduced, and occurrence of a conduction failure and a resistance variation can be significantly reduced.

### Second Embodiment

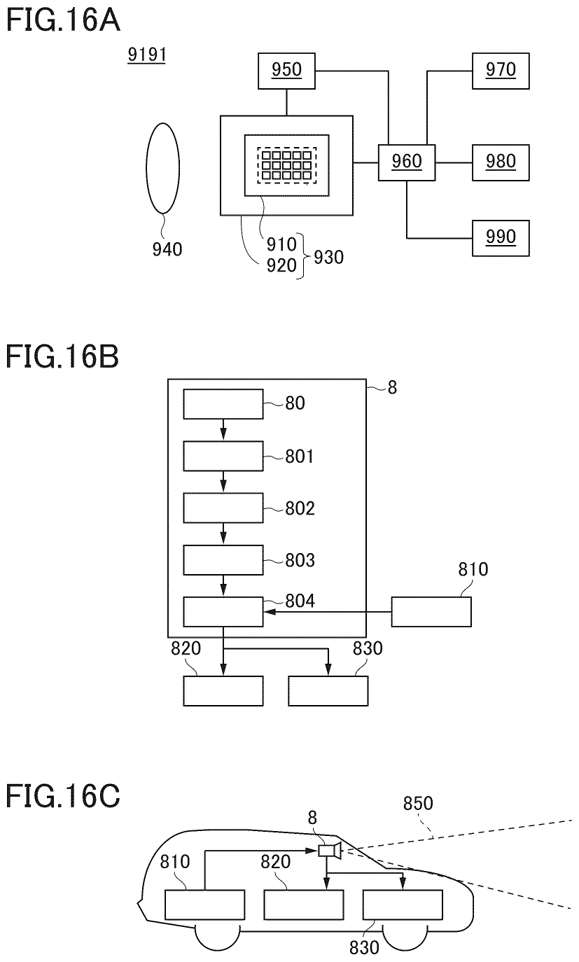

As a second embodiment, equipment including the semiconductor apparatus (solid-state imaging apparatus) according to the above-described embodiment will be described. FIG. 16A is a schematic diagram for describing equipment 9191 including a semiconductor apparatus 930 according to the above-described embodiment. The equipment 9191 including the semiconductor apparatus 930 will be described in detail.

The semiconductor apparatus 930 includes a semiconductor device 910 in which a first chip serving as a photoelectric conversion apparatus and a second chip including at least one of a memory circuit and a logic circuit are integrated. In addition to the semiconductor device 910, the semiconductor apparatus 930 may further include a package 920 that houses the semiconductor device 910. The package 920 can include a base to which the semiconductor device 910 is fixed and a lid such as glass that faces the semiconductor device 910. The package 920 can further include a bonding member such as a bonding wire or a bump that connects a terminal provided on the base and a terminal provided on the semiconductor device 910.

The equipment 9191 can include at least one of an optical apparatus 940, a control apparatus 950, a processing apparatus 960, a display apparatus 970, a storage apparatus 980, and a mechanical apparatus 990. The optical apparatus 940 is, for example, a lens, a shutter, or a mirror provided corresponding to the semiconductor apparatus 930, and includes an optical system that guides light to the semiconductor apparatus 930. The control apparatus 950 controls the semiconductor apparatus 930. The control apparatus 950 is, for example, a semiconductor apparatus such as an application specific integrated circuit (ASIC).

The processing apparatus 960 processes a signal output from the semiconductor apparatus 930. The processing apparatus 960 is a semiconductor apparatus such as a central processing unit (CPU) or an ASIC for configuring an analog front end (AFE) or a digital front end (DFE). The display apparatus 970 is an EL display apparatus or a liquid crystal display apparatus that displays information (image) obtained by the semiconductor apparatus 930. The storage apparatus 980 is a magnetic device or a semiconductor device that stores information (image) obtained by the semiconductor apparatus 930. The storage apparatus 980 is a volatile memory such as a static random-access memory (SRAM) or a dynamic random-access memory (DRAM), or a nonvolatile memory such as a flash memory or a hard disk drive.

The mechanical apparatus 990 includes a movable unit or a propulsion unit such as a motor or an engine. In the equipment 9191, a signal output from the semiconductor apparatus 930 is displayed on the display apparatus 970 or is transmitted to the outside by a communication apparatus (not shown) included in the equipment 9191. Therefore, the equipment 9191 may further includes the storage apparatus 980 and the processing apparatus 960 separately from a storage circuit and an arithmetic circuit of the semiconductor apparatus 930. The mechanical apparatus 990 may be controlled based on a signal output from the semiconductor apparatus 930.

Furthermore, the equipment 9191 is suitable for electronic equipment such as an information terminal (for example, a smartphone or a wearable terminal) having an imaging function or a camera (for example, an interchangeable lens camera, a compact camera, a video camera, or a surveillance camera). The mechanical apparatus 990 in the camera can drive components of the optical apparatus 940 for zooming, focusing, and shutter operations. Alternatively, the mechanical apparatus 990 in the camera can move the semiconductor apparatus 930 for a vibration-proof operation.

Furthermore, the equipment 9191 can be transportation equipment such as a vehicle, a ship, or an aircraft. The mechanical apparatus 990 in the transportation equipment can be used as a movement apparatus. The equipment 9191 serving as transportation equipment is suitable for transporting the semiconductor apparatus 930 and assisting and/or automating driving (steering) by the imaging function. The processing apparatus 960 for assisting and/or automating the driving (steering) can perform processing for operating the mechanical apparatus 990 serving as the movement apparatus based on information obtained by the semiconductor apparatus 930. Alternatively, the equipment 9191 may be medical equipment such as an endoscope, measurement equipment such as a distance measurement sensor, analytical equipment such as an electron microscope, office equipment such as a copying machine, or industrial equipment such as a robot. According to the above-described embodiment, since an electrical resistance at a connection portion between conductive members such as vias and plugs is reduced in an imaging element or a circuit portion, it is possible to stably acquire an image with favorable characteristics.

Therefore, if the semiconductor apparatus 930 according to the present embodiment is used for the equipment 9191, the value of the equipment can also be improved. For example, it is possible to obtain excellent performance when the semiconductor apparatus 930 is mounted on the transportation equipment and performs imaging of the outside of the transportation equipment or measurement of an external environment. Therefore, in manufacturing and selling the transportation equipment, it is advantageous to determine to mount the semiconductor apparatus according to the present embodiment on the transportation equipment in order to enhance the performance of the transportation equipment itself. In particular, the semiconductor apparatus 930 is suitable for transportation equipment that performs driving assistance and/or automated driving of the transportation equipment by using information obtained by the semiconductor apparatus. Implementation in a vehicle, a ship, a flying body, and the like is not limited to application to equipment practically used for transportation purposes, and can be suitably applied to, for example, a drone or the like that performs aerial imaging for various purposes including inspection of buildings and agricultural facilities, monitoring of natural phenomena, and the like.

A photoelectric conversion system and a mobile body according to the present embodiment will be described with reference to FIGS. 16B and 16C. FIG. 16B shows an example of the photoelectric conversion system related to an in-vehicle camera. A photoelectric conversion system 8 includes a photoelectric conversion apparatus 80. The photoelectric conversion apparatus 80 is a photoelectric conversion apparatus serving as an electronic component described in the above-described embodiment. The photoelectric conversion system 8 includes an image processing unit 801 that performs image processing on a plurality of pieces of image data acquired by the photoelectric conversion apparatus 80, and a parallax acquisition unit 802 that calculates a parallax (a phase difference of a parallax image) from the plurality of pieces of image data acquired by the photoelectric conversion system 8. Furthermore, the photoelectric conversion system 8 includes a distance acquisition unit 803 that calculates a distance to a target object based on the calculated parallax, and a collision determination unit 804 that determines whether or not there is a possibility of collision based on the calculated distance. Here, the parallax acquisition unit 802 and the distance acquisition unit 803 are examples of a distance information acquisition unit that acquires distance information to the target object. That is, the distance information is information regarding the parallax, a defocus amount, the distance to the target object, and the like. The collision determination unit 804 may determine the possibility of collision by using any one of these pieces of distance information. The distance information acquisition unit may be implemented by dedicated hardware or may be implemented by a software module. Alternatively, the distance information acquisition unit may be implemented by a field programmable gate array (FPGA), an application specific integrated circuit (ASIC), or the like.

The photoelectric conversion system 8 is connected to a vehicle information acquisition apparatus 810, and can acquire vehicle information such as a vehicle speed, a yaw rate, and a steering angle. In addition, the photoelectric conversion system 8 is connected to a control electronic control unit (ECU) 820 which is a control apparatus that outputs a control signal for generating a braking force on the vehicle based on a determination result of the collision determination unit 804. The photoelectric conversion system 8 is also connected to a warning apparatus 830 that issues a warning to a driver based on the determination result of the collision determination unit 804. For example, in a case where the determination result of the collision determination unit 804 indicates that the possibility of collision is high, the control ECU 820 performs vehicle control to avoid collision and reduce damage by applying a brake, returning an accelerator, reducing an engine output, or the like. The warning apparatus 830 issues a warning to a user by emitting warnings such as sound, displaying warning information on a screen of a car navigation system or the like, providing vibrations to a seat belt or a steering wheel, or the like.

In the present embodiment, the photoelectric conversion system 8 images the periphery of the vehicle, for example, an area in front of or behind the vehicle. FIG. 16C shows the photoelectric conversion system in a case of imaging the area (imaging range 850) in front of the vehicle. The vehicle information acquisition apparatus 810 sends an instruction to the photoelectric conversion system 8 or the photoelectric conversion apparatus 80. With such a configuration, accuracy of distance measurement can be further improved.

In the above description, an example of performing control to prevent collision with another vehicle has been described, but the present technology is also applicable to control for performing automated driving following another vehicle, control for performing automated driving so as not to stray from a lane, and the like. Furthermore, the photoelectric conversion system is not limited to the vehicle such as an automobile, and can be applied to a mobile body (mobile apparatus) such as a ship, an aircraft, or an industrial robot, for example. In addition, the present technology can be applied not only to a mobile body but also to equipment that widely uses object recognition, such as an intelligent transport system (ITS). According to the above-described embodiment, it is possible to stably acquire an image having favorable characteristics.

### Third Embodiment

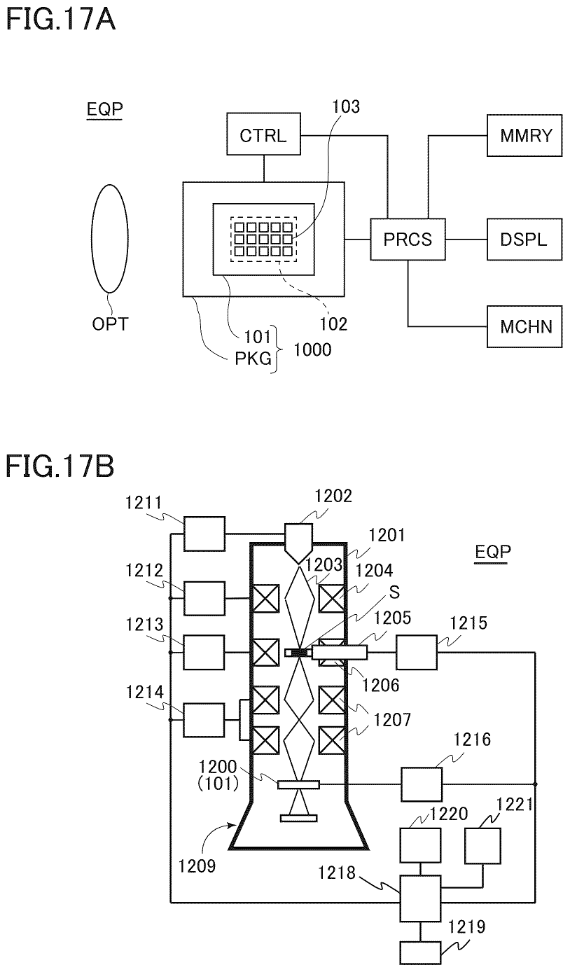

As a third embodiment, an example of a radiation imaging system in which the semiconductor apparatus described in the first embodiment is used as a radiation detector and the radiation detector is incorporated will be described with reference to FIGS. 17A and 17B.

FIG. 17A shows equipment EQP serving as the radiation imaging system including a radiation detector 1000. The radiation detector 1000 includes a package PKG for mounting an imaging element 101 in addition to an imaging element 101 (a photoelectric conversion element capable of detecting radiation) which is a semiconductor device.

The package PKG may include a base to which the imaging element 101 is fixed, a lid such as glass facing the imaging element 101, and a connection member such as a bonding wire or a bump that connects a terminal provided on the base and a terminal provided on the imaging element 101. The imaging element 101 includes a pixel array 102 in which pixels 103 are arranged in a matrix and a peripheral region around the pixel array 102. A peripheral circuit (for example, a vertical scanning circuit and a DFE) can be provided in the peripheral region.

The equipment EQP may further include at least one of an optical system OPT, a control apparatus CTRL, a processing apparatus PRCS, a display apparatus DSPL, a storage apparatus MMRY, and a mechanical apparatus MCHN. The optical system OPT forms an image of radiation on the radiation detector 1000, and is, for example, a lens, a shutter, or a mirror. The optical system OPT may form an image of a particle beam such as an electron beam or a proton beam on the radiation detector 1000 according to a type of radiation to be handled. The control apparatus CTRL controls the radiation detector 1000, and is, for example, an ASIC. The processing apparatus PRCS processes a signal output from the radiation detector 1000, and is an apparatus such as a CPU or an ASIC for configuring an analog front end (AFE) or a digital front end (DFE). The display apparatus DSPL is an electroluminescence (EL) display apparatus or a liquid crystal display apparatus that displays information obtained by the radiation detector 1000 in a form of a visible image or the like. The storage apparatus MMRY is a magnetic device or a semiconductor device that stores information obtained by the radiation detector 1000. The storage apparatus MMRY is a volatile memory such as an SRAM or a DRAM, or a nonvolatile memory such as a flash memory or a hard disk drive. The mechanical apparatus MCHN includes a movable unit such as a motor.

The equipment EQP displays a signal output from the radiation detector 1000 on the display apparatus DSPL or transmits the signal to the outside by a communication apparatus (not shown) included in the equipment EQP. Therefore, the equipment EQP may further includes the storage apparatus MMRY and the processing apparatus PRCS separately from a storage circuit and an arithmetic circuit of the radiation detector 1000. The mechanical apparatus MCHN may be controlled based on a signal output from the radiation detector 1000.

The equipment EQP shown in FIG. 17A may be medical equipment such as an endoscope or radiodiagnosis equipment, measurement equipment such as a distance measurement sensor, or analytical equipment such as an electron microscope.

FIG. 17B is a schematic diagram showing a configuration of a transmission electron microscope (TEM) as an example of the equipment EQP. The equipment EQP serving as an electron microscope includes an electron beam source 1202 (electron gun), an application lens 1204, a vacuum chamber 1201 (lens barrel), an objective lens 1206, a magnifying lens system 1207, and a camera 1209 serving as the radiation detector 1000.

The electron beam 1203, which is an energy beam emitted from the electron beam source 1202 (radiation source), is focused by the application lens 1204 and is applied to a sample S serving as an analysis target (imaging target) held by a sample holder. A space through which the electron beam 1203 passes is formed by the vacuum chamber 1201 (lens barrel), and the space is held in vacuum. The radiation detector 1000 is disposed to face the vacuum space through which the electron beam 1203 passes. The electron beam 1203 transmitted through the sample S is enlarged by the objective lens 1206 and the magnifying lens system 1207 and projected onto the radiation detector 1000. An electron optical system for applying the electron beam to the sample S is referred to as an application optical system, and an electron optical system for forming an image of the electron beam transmitted through the sample S on the radiation detector 1000 is referred to as an imaging optical system.

The electron beam source 1202 is controlled by an electron beam source control apparatus 1211. The application lens 1204 is controlled by an application lens control apparatus 1212. The objective lens 1206 is controlled by an objective lens control apparatus 1213. The magnifying lens system 1207 is controlled by a magnifying lens system control apparatus 1214. A control mechanism 1205 of the sample holder is controlled by a holder control apparatus 1215 that controls a drive mechanism of the sample holder.

The electron beam 1203 transmitted through the sample S is detected by a direct electron detector 1200 of the camera 1209. An output signal from the direct electron detector 1200 is processed by a signal processing apparatus 1216 and an image processing apparatus 1218 serving as the processing apparatuses PRCS to generate an image signal. The generated image signal (transmitted electron image) is displayed on an image display monitor 1220 and an analysis monitor 1221 corresponding to the display apparatus DSPL.

The camera 1209 is provided at the bottom of the equipment EQP. The camera 1209 includes the direct electron detector 1200. The direct electron detector 1200 corresponds to the imaging element 101. The direct electron detector 1200 is provided in the camera 1209 such that at least a part of the camera 1209 is exposed to the vacuum space formed by the vacuum chamber 1201.

Each of the electron beam source control apparatus 1211, the application lens control apparatus 1212, the objective lens control apparatus 1213, the magnifying lens system control apparatus 1214, and the holder control apparatus 1215 is connected to the image processing apparatus 1218. As a result, data can be exchanged with each other in order to set imaging conditions of the electron microscope. For example, an application rate of the electron beam can be set so as to be 0.5 electron/pix/frm or less. In this case, the electron beam source control apparatus 1211 and the image processing apparatus 1218 function as a control unit that controls a radiation application rate. Drive control of the sample holder and observation conditions of each lens can be set by a signal from the image processing apparatus 1218.

An operator prepares the sample S to be imaged, and sets imaging conditions by using an input apparatus 1219 connected to the image processing apparatus 1218. Predetermined data is input to each of the electron beam source control apparatus 1211, the application lens control apparatus 1212, the objective lens control apparatus 1213, and the magnifying lens system control apparatus 1214, and a desired acceleration voltage, magnification, and observation mode are obtained. In addition, the operator inputs conditions such as the number of consecutive visual field images, an imaging start position, and a movement speed of the sample holder to the image processing apparatus 1218 by using the input apparatus 1219 such as a mouse, a keyboard, or a touch panel. Alternatively, the image processing apparatus 1218 may automatically set the conditions without depending on the operator's input. The radiation imaging system described in the embodiment is merely an example, and the semiconductor apparatus described in the first embodiment may be applied to other systems.

### Modified Embodiment

The present disclosure is not limited to the embodiments and modified examples described above, and many modifications can be made within the technical idea of the present disclosure. For example, all or some of the different embodiments and modified examples described above may be combined and implemented.

For example, the semiconductor apparatus described in the embodiment may be applied to a detector using a single photon avalanche diode (SPAD) and an imaging system including the same.

The application of the semiconductor apparatus described in the embodiment is not limited to imaging. For example, the semiconductor apparatus described in the embodiment is also applicable to a distance measurement apparatus (an apparatus for focus detection, distance measurement using time of flight (TOF), or the like), a photometric apparatus (an apparatus for measuring an incident light quantity or the like), or the like.

The photoelectric conversion apparatus to which the present disclosure can be applied is not limited to a specific form, and may be, for example, any one of a front-illuminated type sensor and a back-side illuminated type sensor. Alternatively, the photoelectric conversion apparatus may be a stacked-type photoelectric conversion apparatus in which a semiconductor chip including a light receiving unit and a semiconductor chip including an electric circuit such as a logic circuit are stacked.

Various types of equipment including the semiconductor apparatus according to the embodiment are also included in the embodiment of the present disclosure. The equipment according to the embodiment can include at least one of six apparatuses including the optical apparatus corresponding to the semiconductor apparatus, the control apparatus that controls the semiconductor apparatus, the processing apparatus that processes information obtained from the semiconductor apparatus, the display apparatus that displays information obtained from the semiconductor apparatus, the storage apparatus that stores information obtained from the semiconductor apparatus, and the mechanical apparatus that operates based on information obtained from the semiconductor apparatus.

According to the present disclosure, it is possible to provide a technology advantageous for reducing an electrical resistance at a connection portion between conductive members such as vias and plugs in a semiconductor apparatus.

### Other Embodiments

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-200025, filed Nov. 15, 2024, which is hereby incorporated by reference herein in its entirety.

What is claimed is:

1. A semiconductor apparatus comprising:
a semiconductor layer;
an insulating layer stacked on the semiconductor layer;
a through via having conductivity, penetrating the semiconductor layer, extending into the insulating layer, having a recess at an end portion on a side adjacent to the insulating layer; and
a connection member having conductivity, disposed in the insulating layer, having a side surface a part of which being in contact with an inner side surface of the recess of the through via,
wherein the part of the side surface of the connection member, which is in contact with the through via, extends from a side of the insulating layer to a side of the semiconductor layer with respect to an extension line of an interface between the insulating layer and the semiconductor layer.

2. The semiconductor apparatus according to claim 1, further comprising:
a first substrate including a first semiconductor layer and a first insulating layer,
wherein the insulating layer and the semiconductor layer are included in a second substrate, and
wherein the first substrate and the second substrate are bonded to each other such that the first insulating layer and the insulating layer are adjacent to each other.

3. The semiconductor apparatus according to claim 2, wherein
the first semiconductor layer includes a photoelectric conversion element, and the second substrate includes an electric circuit that processes a signal output from the first substrate.

4. The semiconductor apparatus according to claim 1, further comprising:
a third substrate including a third semiconductor layer and a third insulating layer,
wherein the insulating layer and the semiconductor layer are included in a second substrate, the second substrate further includes a second insulating layer formed on the semiconductor layer on a side opposite to the insulating layer, and
wherein the third substrate and the second substrate are bonded to each other such that the second insulating layer and the third insulating layer are adjacent to each other.

5. The semiconductor apparatus according to claim 1, wherein the through via includes a first core material having conductivity, and
wherein a first covering material having conductivity, the first covering material covering the first core material.

6. The semiconductor apparatus according to claim 5, wherein a thickness of the first covering material covering a side surface of the first core material is substantially equal to a thickness of the first covering material covering a bottom surface of the recess of the first core material.

7. The semiconductor apparatus according to claim 5, wherein a thickness of the first covering material covering a side surface of the first core material is smaller than a thickness of the first covering material covering a bottom surface of the recess of the first core material.

8. The semiconductor apparatus according to claim 1, wherein the connection member includes a second core material having conductivity and a second covering material having conductivity, the second covering material covering the second core material.

9. The semiconductor apparatus according to claim 8, wherein a thickness of the second covering material covering a side surface of the second core material is substantially equal to a thickness of the second covering material covering an end surface of the second core material on a side adjacent to the through via.

10. The semiconductor apparatus according to claim 8, wherein a thickness of the second covering material covering a side surface of the second core material is smaller than a thickness of the second covering material covering an end surface of the second core material on a side adjacent to the through via.

11. An imaging apparatus comprising:
the semiconductor apparatus according to claim 1; and
an optical apparatus corresponding to the semiconductor apparatus.

12. A radiation imaging system comprising:
the semiconductor apparatus according to claim 1; and
a radiation source configured to apply radiation to an imaging target.

13. An equipment comprising:
the semiconductor apparatus according to claim 1; and
an apparatus selected from the group consisting of:
an optical apparatus corresponding to the semiconductor apparatus,
a control apparatus that controls the semiconductor apparatus,
a processing apparatus that processes information obtained from the semiconductor apparatus,
a display apparatus that displays information obtained from the semiconductor apparatus,
a storage apparatus that stores information obtained from the semiconductor apparatus, and
a mechanical apparatus that operates based on information obtained from the semiconductor apparatus.

14. A semiconductor apparatus manufacturing method comprising:
preparing a second substrate including a semiconductor layer in which semiconductor elements are formed, an element isolation region that isolates the semiconductor elements, and an insulating layer provided so as to cover the semiconductor layer and the element isolation region;
forming, in the second substrate, a first opening that penetrates the insulating layer and reaches a part of the element isolation region;
forming a connection member having conductivity by filling the first opening with a conductive material;
forming, in the second substrate, a second opening that penetrates the semiconductor layer and the element isolation region, reaches a part of the insulating layer, and exposes a part of the connection member; and
forming a through via having conductivity by filling the second opening with the conductive material,
wherein an electrical connection structure in which the through via and the connection member are bonded to each other is formed, the through via penetrating the semiconductor layer, extending into the insulating layer, and having a recess at an end portion on a side adjacent to the insulating layer, the connection member being disposed in the insulating layer and having a part of a side surface in contact with an inner side surface of the recess of the through via.

15. The semiconductor apparatus manufacturing method according to claim 14, wherein the part of the side surface of the connection member that is in contact with the through via extends from a side of the insulating layer to a side of the semiconductor layer with respect to an extension line of an interface between the insulating layer and the semiconductor layer.

16. The semiconductor apparatus manufacturing method according to claim 14, further comprising:
preparing a first substrate including a first semiconductor layer and a first insulating layer, and
bonding the second substrate and the first substrate to each other such that the first insulating layer and the insulating layer are adjacent to each other.

17. The semiconductor apparatus manufacturing method according to claim 14 further comprising:
preparing a third substrate including a third semiconductor layer and a third insulating layer, and
bonding the third substrate and the second substrate to each other such that the second insulating layer and the third insulating layer are adjacent to each other,
wherein the second substrate includes a second insulating layer formed on the semiconductor layer on a side opposite to the insulating layer.

18. The semiconductor apparatus manufacturing method according to claim 14, wherein the forming of the through via includes:
forming a first covering material having conductivity in the second opening; and
forming a first core material having conductivity in the second opening in which the first covering material is formed.

19. The semiconductor apparatus manufacturing method according to claim 18, wherein in the forming of the first covering material,
the first covering material is formed such that a thickness of the first covering material covering a side surface of the first core material is substantially equal to a thickness of the first covering material covering an end surface of the first core material on a side adjacent to the insulating layer.

20. The semiconductor apparatus manufacturing method according to claim 18, wherein in the forming of the first covering material,
the first covering material is formed such that a thickness of the first covering material covering a side surface of the first core material is smaller than a thickness of the first covering material covering an end surface of the first core material on a side adjacent to the insulating layer.

21. The semiconductor apparatus manufacturing method according to claim 14, wherein the forming of the connection member includes:
forming a second covering material in the first opening; and
forming a second core material having conductivity in the first opening in which the second covering material is formed.

22. The semiconductor apparatus manufacturing method according to claim 21, wherein in the forming of the second covering material,
the second covering material is formed such that a thickness of the second covering material covering a side surface of the second core material is substantially equal to a thickness of the second covering material covering an end surface of the second core material on a side adjacent to the through via.

23. The semiconductor apparatus manufacturing method according to claim 21, wherein in the forming of the second covering material,
the second covering material is formed such that a thickness of the second covering material covering a side surface of the second core material is smaller than a thickness of the second covering material covering an end surface of the second core material on a side adjacent to the through via.
